(19) United States
(12) Patent Application Publication
(10) Pub. No.: US 2008/0012112 A1
(43) Pub. Date: Jan. 17, 2008

(54) SEMICONDUCTOR PACKAGE HAVING ADVANTAGE FOR STACKING AND STACK-TYPE SEMICONDUCTOR PACKAGE

(75) Inventor: Young-Min LEE, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/752,790

(22) Filed: May 23, 2007

(30) Foreign Application Priority Data
Jul. 12, 2006 (KR) 2006-0065471

(51) Int. Cl. H01L 23/02

(52) U.S. Cl. 257/686; 257/E23.18

(57) ABSTRACT

Provided are a semiconductor package having an advantage for stacking and a stack-type semiconductor package using the semiconductor package. In one embodiment, the semiconductor package includes a wing-type substrate comprising a first surface, a second surface opposite the first surface, a chip pad area, an external terminal area on the first surface and a stack-type terminal pad on the second surface, wherein the chip pad area is lower than the external terminal area; a semiconductor chip mounted on the wing-type substrate within the chip pad area, wherein the semiconductor chip is electrically connected to the wing-type substrate; a sealing part on the wing-type substrate, the sealing part sealing the semiconductor chip and the wing-type substrate; and a conductive connecting member on the external terminal area, wherein a height of the conductive connecting member is greater than a height of the wing-type substrate.

### CROSS-REFERENCE TO RELATED PATENT APPLICATION

This application claims the benefit of Korean Patent Application No. 10-2006-0065471, filed on Jul. 12, 2006, the disclosure of which is incorporated herein in its entirety by reference.

### BACKGROUND

1. Field of Invention

Embodiments of the present invention relate generally to semiconductor package structures and more particularly to a semiconductor package capable of lowering the height of a stack structure using the semiconductor package and solving several problems occurring during stacking, and also to a stack-type semiconductor package using the semiconductor package.

2. Description of the Related Art

Electronic appliances have been developed with a focus on compactness, weight, and speed. Semiconductor devices have been changed to meet the development of such electronic appliances.

Improving the integration density of semiconductor chips in a wafer manufacturing process was focused in pursuit of being compact. However, much research, extensive development of equipment, and astronomical cost are required to improve the integration of semiconductor chips in a wafer manufacturing process. To solve these problems, technology for stacking semiconductor chips or semiconductor packages based on memory devices has been developed and introduced.

FIGS. 1 and 2 are cross-sectional views illustrating a semiconductor package and a stack-type semiconductor package using the semiconductor package according to the prior art.

Referring to FIGS. 1 and 2, to manufacture a typical ball grid array package (BGA) 30, a semiconductor chip 14 is bonded to a substrate 10 through an adhesive tape 12. Next, a bond pad (not shown) of the semiconductor chip 14 is connected to a bond finger (not shown) of the substrate 10 using a wire 16. Thereafter, the semiconductor chip 14 and the wires 16 are sealed with a sealing resin 18 to form a package body 22 and solder balls 20 are adhered to a lower surface of the substrate 10.

However, referring to FIG. 2, if a height H1 of the package body 22 is greater than a height of the solder balls 20, it is difficult to stack such semiconductor packages 30 (e.g., semiconductor packages 30A and 30B). If a plurality of semiconductor chips are stacked within the package body 22, it becomes even more difficult to stack semiconductor packages 30. Also, if the diameter of the solder balls 20 is decreased (i.e., to be less than H2), it becomes more difficult to stack the semiconductor packages 30.

To make semiconductor packages compact and thin, a plurality of semiconductor chips are often stacked within a single semiconductor package and the diameter of solder balls is reduced to form allow for more terminals in the semiconductor package. Thus, it is difficult to stack semiconductor packages having the structure as shown in FIGS. 1 and 2.

### SUMMARY

Embodiments of the present invention are adapted to provide a thin semiconductor package that can be easily stacked.

One embodiment of the present invention can be exemplarily characterized as a semiconductor package that includes a wing-type substrate. The wing-type substrate includes a first surface, a second surface opposite the first surface, a chip pad area, an external terminal area on the first surface and a stack-type terminal pad on the second surface. The chip pad area may be lower than the external terminal area. The semiconductor package may also include a semiconductor chip mounted on the wing-type substrate within the chip pad area and electrically connected to the wing-type substrate, a sealing part on the wing-type substrate that seals the semiconductor chip and the wing-type substrate, and a conductive connecting member on the external terminal area. A height of the conductive connecting member may be greater than a height of the wing-type substrate.

If there is one semiconductor chip, the semiconductor chip may be mounted within a chip pad area of the wing-type substrate so that a circuit surface faces downward. The semiconductor chip may be a center pad type semiconductor chip comprising a bond pad formed in a center. A slit for wire bonding may be formed in the chip pad area of the wing-type substrate. In this case, the sealing part may be formed on a lower surface of the wing-type substrate.

The semiconductor chip may be mounted within the chip pad area of the wing-type substrate so that a circuit surface faces upward. In this case, the sealing part may be formed above the wing-type substrate.

Two or more semiconductor chips may be mounted within the chip pad area of the wing-type substrate. Bottoms of one or more of the semiconductor chips may be polished to have a thickness within a range of between 50 μm and 100 μm.

If two or more semiconductor chips are used, the semiconductor chips may be mounted within the chip pad area of the wing-type substrate so that a circuit surface of a first semiconductor chip faces downward and a circuit surface of a second semiconductor chip faces upward. In this case, the sealing part may include a first sealing part formed underneath the wing-type substrate and a second sealing part formed on the wing-type substrate. Terminal pads of the external terminal area may be disposed in two rows.

Another embodiment of the present invention can be exemplarily characterized as a semiconductor package that includes a wing-type substrate that includes a first surface, a second surface opposite the first surface, a chip pad area, an external terminal area on the first surface, and a stack-type solder terminal pad on the second surface. The external terminal area may be higher than the chip pad area. The semiconductor package may further include a semiconductor chip within chip pad area and connected to the wing-type substrate by a bump, and a conductive connection member coupled to the external terminal area. A height of the conductive connection member may be greater than a height of the wing-type substrate.

Yet another embodiment of the present invention can be exemplarily characterized as a stack-type semiconductor package that includes a structure in which upper and lower semiconductor packages are stacked. The upper and lower semiconductor packages may be electrically connected to each other using conductive connection members and a stack-type terminal pad.

A further embodiment of the present invention can be exemplarily characterized as a semiconductor package that includes a substrate having a first surface, a second surface opposite the first surface, a third surface, and a fourth surface opposite the third surface. The third surface may be between the second and fourth surfaces. A solder ball may be on at least one of the first and second surfaces, a semiconductor chip may be mounted onto the third surface and electrically connected to the semiconductor chip. A diameter of the solder ball may be greater than a distance between the second surface and the fourth surface.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are cross-sectional views illustrating a semiconductor package and a stack-type semiconductor package using the semiconductor package according to the prior art;

FIGS. 3 through 6 are cross-sectional views illustrating a method of manufacturing a semiconductor package having an advantage for stacking and a structure of a stack-type semiconductor package according to an embodiment of the present invention;

FIGS. 7 through 10 are cross-sectional views illustrating a method of manufacturing a semiconductor package having an advantage for stacking and a structure of a stack-type semiconductor package according to another embodiment of the present invention;

FIGS. 11 through 13 are cross-sectional views illustrating a semiconductor package having an advantage for stacking and a stack-type semiconductor package according to yet another embodiment of the present invention; and

FIGS. 14 through 16 are cross-sectional views illustrating a method of manufacturing a semiconductor package having an advantage for stacking and a structure of a stack-type semiconductor package according to still another embodiment of the present invention.

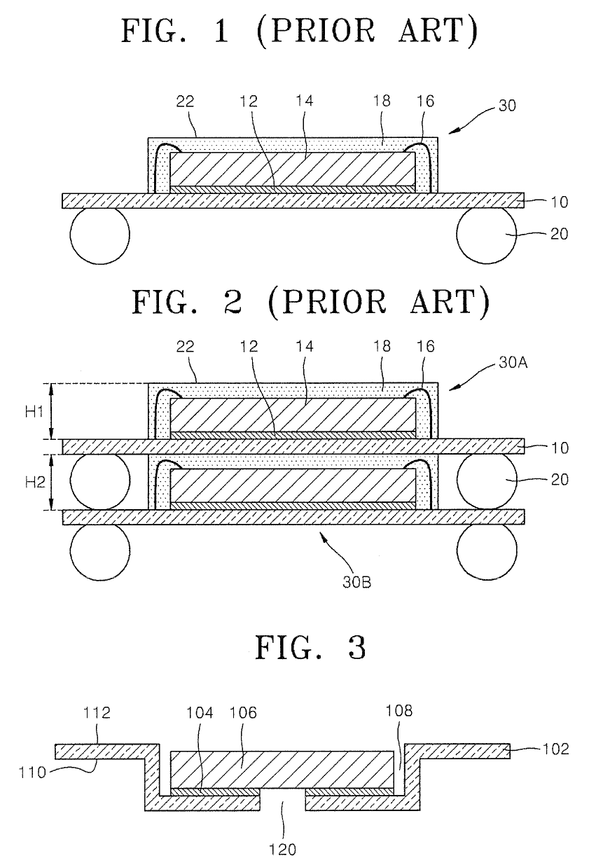

### DETAILED DESCRIPTION

Exemplary embodiments of the present invention will now be described more fully with reference to the accompanying drawings. These embodiments may, however, be realized in many different forms and should not be construed as being limited to the embodiments set forth herein; rather, these embodiments are provided so that this disclosure will be thorough and complete, and will fully convey the concept of the invention to those skilled in the art.

FIGS. 3 through 6 are cross-sectional views illustrating a method of manufacturing a semiconductor package having an advantage for stacking and a structure of a stack-type semiconductor package according to an embodiment of the present invention.

Referring to FIG. 3, a wing-type substrate 102 is provided. The wing-type substrate 102 may, for example, include a chip pad area 108 having a depressed shape adapted to accommodate a semiconductor chip 106. Also, external terminal areas (e.g., solder ball adhering areas) 110 may be formed on a lower surface of the wing-type substrate 102 along an edge of the chip pad area 108, and solder ball pads (not shown) may be formed in the solder ball adhering areas 110. The solder ball pads of the solder ball adhering areas 110 may extend through penetration holes (not shown) formed in the wing-type substrate 102 to stack-type terminal pads (e.g., stack-type solder ball pads) 112 having electric functions on the wing-type substrate 102.

A slit 120 may be formed in the center of the chip pad area 108 as a space in which wire bonding is performed to electrically connect the semiconductor chip 106 to the wing-type substrate 102. The semiconductor chip 106 may be bonded to the chip pad area 108 of the wing-type substrate 102 using an adhesive 104 (e.g., adhesive tape, liquid epoxy, or the like). Here, the semiconductor chip 106 may be bonded so that a circuit surface of the semiconductor chip 106 faces downward (i.e., toward the chip pad area 108), and a bond pad (not shown) may be formed in the center of the circuit surface of the semiconductor chip 106.

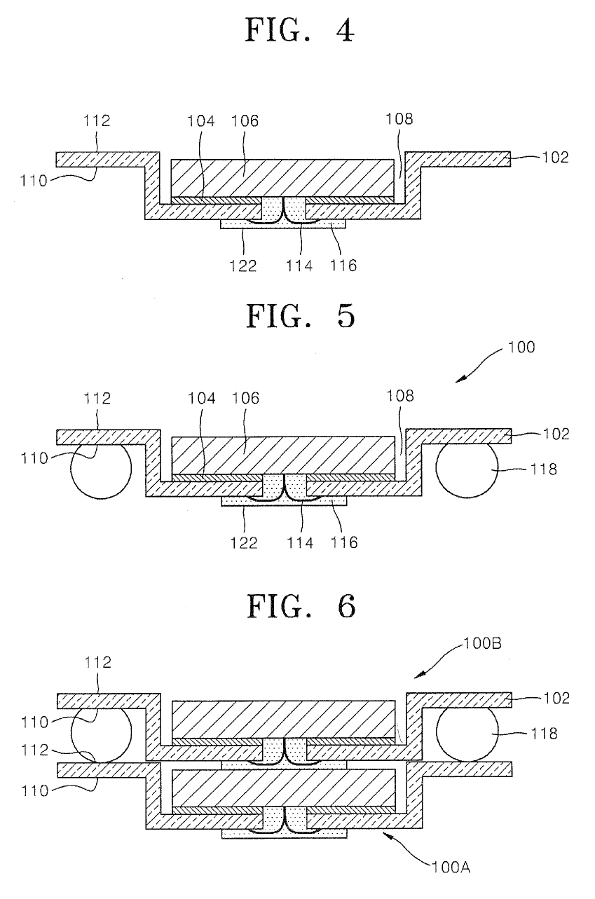

Referring to FIGS. 4 and 5, the bond pad in the center of the semiconductor chip 106 may be connected to a bond finger (not shown) on the lower surface of the wing-type substrate 102 through the slit 120 of the wing-type substrate 102 using wires 114. Accordingly, the semiconductor chip 106 may be electrically connected to the wing-type substrate 102 via a bond finger. An exposed portion of the semiconductor chip 106 and the wires 114 may be sealed by a sealant (e.g., resin) 116 to form a sealing part 122 on the lower surface of the wing-type substrate 102. Conductive connecting members (e.g., solder balls, conductive pillars, etc.) 118 are adhered to the solder ball pads of the solder ball adhering area 110 and a lower surface of the edge of the wing-type substrate 102 to complete manufacture of a semiconductor package 100.

A structure of the semiconductor package 100 according to the present embodiment will now be described with reference to FIG. 5.

As shown in FIG. 5, the semiconductor package 100 may include the wing-type substrate 102, the semiconductor chip 106 including the circuit surface facing downward, the sealing part 122 formed on the lower portion of the wing-type substrate 102, and the solder balls 118 adhered to the lower portion of the edge of the wing-type substrate 102.

In the illustrated embodiment, the wing-type substrate 102, the semiconductor chip 106 and the sealing part 122 may be formed to have a height encompassing the diameter of the solder balls 118, due to the chip pad area having the depressed shape. Thus, a final height of the semiconductor package 100 is reduced as compared with the semiconductor package 30 of the prior art. That is, the solder balls 118 may have a diameter (i.e., height) that is greater than the height of the wing-type substrate 102 from the solder ball adhering area 110 on the lower surface of the wing-type substrate 102 to a lower surface of the wing-type substrate 102 where the sealing part 122 is located. As a result, a portion of the solder balls 118 lies within the same plane as the lower surface of the wing-type substrate 102. Accordingly, the diameter of the solder balls 118 may be decreased relative to the diameter of the solder balls 20 of the prior art and/or a plurality of semiconductor chips may be stacked within the semiconductor package 100, thereby allowing a stack-type semiconductor package to be easily realized.

FIG. 6 is a cross-sectional view illustrating a stack-type semiconductor package realized using multiple semiconductor packages such as those exemplarily shown in FIG. 5.

As shown in FIG. 6, stack-type solder ball pads 112 of a first semiconductor package 100A may be connected to corresponding solder balls 118 of a second semiconductor package 100B to electrically connect the first semiconductor package 100A to the second semiconductor package 100B. The stack-type semiconductor package shown in FIG. 6 has an advantage of increasing the overall height of a side using a space of a chip pad area of a wing-type substrate 102. Thus, when a plurality of semiconductor chips 106 are stacked (see, e.g., FIG. 11) or the diameter of solder balls is decreased during stacking of semiconductor packages, typical problems occurring due to stacking may be avoided.

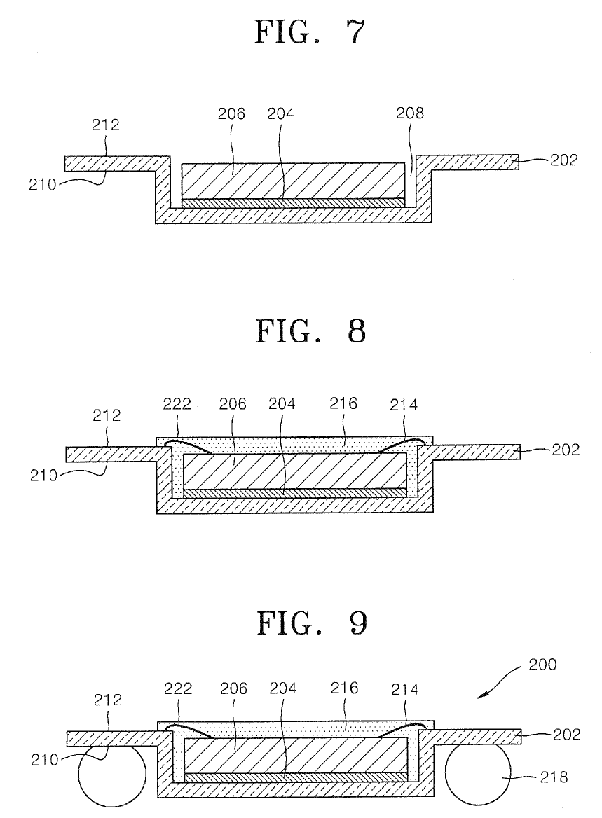

FIGS. 7 through 10 are cross-sectional views illustrating a method of manufacturing a semiconductor package having an advantage for stacking and a structure of a stack-type semiconductor package according to another embodiment of the present invention.

Referring to FIG. 7, a wing-type substrate 202 may be provided as a basic frame of a semiconductor package. Here, the wing-type substrate 202 is similar to the wing-type substrate 102 exemplarily described with respect to FIG. 5 but is different from the wing-type substrate 102 in that a slit is not formed in the bottom of a chip pad area 208.

A semiconductor chip 206 may be bonded to the wing-type substrate 202 using an adhesive 204 (e.g., adhesive tape). In the illustrated embodiment, a circuit surface of the semiconductor chip 206 faces upward (i.e., away from the chip pad area 108), unlike the embodiment illustrated in FIG. 5. Also, the semiconductor chip 206 may be an edge pad-type chip in which a bond pad (not shown) is formed along an edge of the semiconductor chip 206.

Referring to FIGS. 8 and 9, the bond pad at the edge of the semiconductor chip 206 may be connected to a bond finger (not shown) formed on a surface of the wing-type substrate 202 using wires 214. Also, a sealing part 222 is formed on the wing-type substrate 202 using a sealant (e.g., sealing resin) 216 so as to seal the semiconductor chip 206 and the wires 214. Thereafter, solder balls 218 are adhered to a solder ball pad (not shown) of a solder ball adhering area 210 of the wing-type substrate 202.

A structure of the semiconductor package 200 according to the present embodiment will now be described with reference to FIG. 9.

As shown in FIG. 9, the semiconductor package 200 may include the wing-type substrate 202, the semiconductor chip 206 mounted in a chip pad area 208 of the wing-type substrate 202, the sealing part 222 formed above the wing-type substrate 202, and the solder balls 218 adhered to the lower portion of the edge of the wing-type substrate 202.

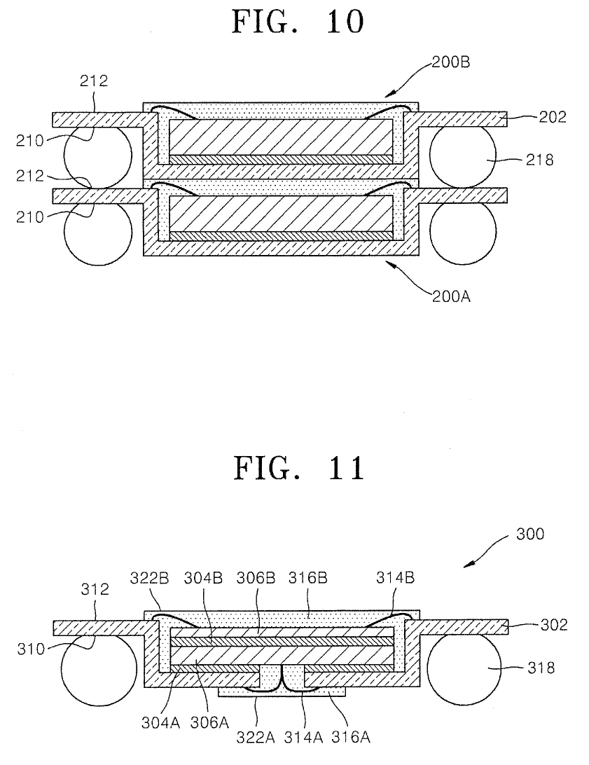

FIG. 10 is a cross-sectional view illustrating a stack-type semiconductor package realized using multiple semiconductor packages such as those exemplarily shown in FIG. 9.

As shown in FIG. 10, stack-type solder ball pads 212 of a first semiconductor package 200A may be connected to corresponding solder balls 218 of a second semiconductor package 200B to electrically connect the semiconductor package 200A to the second semiconductor package 200B.

FIGS. 11 through 13 are cross-sectional views illustrating a semiconductor package having an advantage for stacking and a stack-type semiconductor package according to yet another embodiment of the present invention.

Referring to FIG. 11, a wing-type substrate 302 may be provided. Here, the wing-type substrate 302 is similar to the wing-type substrates 102 and 202 exemplarily described with respect to FIGS. 5 and 9.

A semiconductor chip 306A may be bonded to a chip pad area of the wing-type substrate 302 using a first adhesive 304A (e.g., adhesive tape). The first semiconductor chip 306A is mounted in the chip pad area so that a bond pad (not shown) formed in the center of the first semiconductor chip 306A and a circuit surface of the first semiconductor chip 306A faces downward. Wire bonding is performed using first wires 314A, and a sealing part 322A is formed on a lower surface of the wing-type substrate 302 using a first sealant 316A (e.g., sealing resin).

A second adhesive 304B (e.g., adhesive tape) is adhered on the first semiconductor chip 306A and a second semiconductor chip 306B is mounted on the second adhesive 304B. The second semiconductor chip 306B may be an edge pad type chip in which a circuit surface faces upward and a bond pad is formed along an edge of the second semiconductor chip 306B. The second semiconductor chip 306B is electrically connected to the wing-type substrate 302 using second wires 314B, and a second sealing part 322B is formed on the wing-type substrate 302 using a second sealant 316B (e.g., sealing resin). Solder balls 318 may be adhered to a solder ball pad (not shown) of a solder ball adhering area 310 of the wing-type substrate 302.

In one embodiment, bottom surface of the first and second semiconductor chips 306A and 306B may be polished. In another embodiment, the first and second semiconductor chips 306A and 306B may have a thickness within a range of between 50 μm and 100 μm.

Constructed as described above, the semiconductor package 300 is a combination of the semiconductor packages 100 and 200 exemplarily described above with respect to FIGS. 5 and 9 and further allows two semiconductor chips (e.g., first and second semiconductor chips 306A and 306B) to be stacked within a chip pad area. Thus, the sealing parts 322A and 322B may be formed on and underneath the wing-type substrate 302.

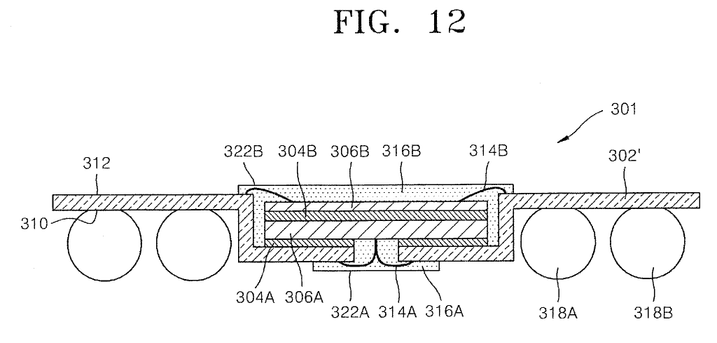

FIG. 12 is a cross-sectional view illustrating a modification of the semiconductor package 300 shown in FIG. 11.

Referring to FIG. 12, a plurality of semiconductor chips 306a and 306B may be stacked in a chip pad area of a wing-type substrate 302′. Thus, the number of external connection ports used in the wing-type substrate 302′ may be increased over the number of external connection ports used in the wing-type substrate 302 shown in FIG. 11. As a result, the solder ball pad structure (e.g., solder ball pads in a single row) as shown in FIG. 11 may not accommodate the increased number of external connection ports. In this case, solder ball pads may be disposed in two rows as shown in FIG. 12, and solder balls 318A and 318B may be adhered to the solder ball pads. As a result, a semiconductor package having an advantage for stacking may be realized and a lack of external connection ports may be solved. While the embodiment illustrated in FIG. 12 shows wherein the solder balls 318A and 318B are disposed in two rows, it will be appreciated that the solder balls 318A and 318B may be disposed in any number of rows (e.g., three or more rows).

FIG. 13 is a cross-sectional view illustrating a stack-type semiconductor package realized using multiple semiconductor packages such as those exemplarily shown in FIG. 11.

As shown in FIG. 13, stack-type solder ball pads 312 of a first semiconductor package 300A may be connected to corresponding solder balls 318 of a second semiconductor package 300B to electrically connect the first semiconductor package 300A to the second semiconductor package 300B.

FIGS. 14 through 116 are cross-sectional views illustrating a method of manufacturing a semiconductor package having an advantage for stacking and a structure of a stack-type semiconductor package according to still another embodiment of the present invention.

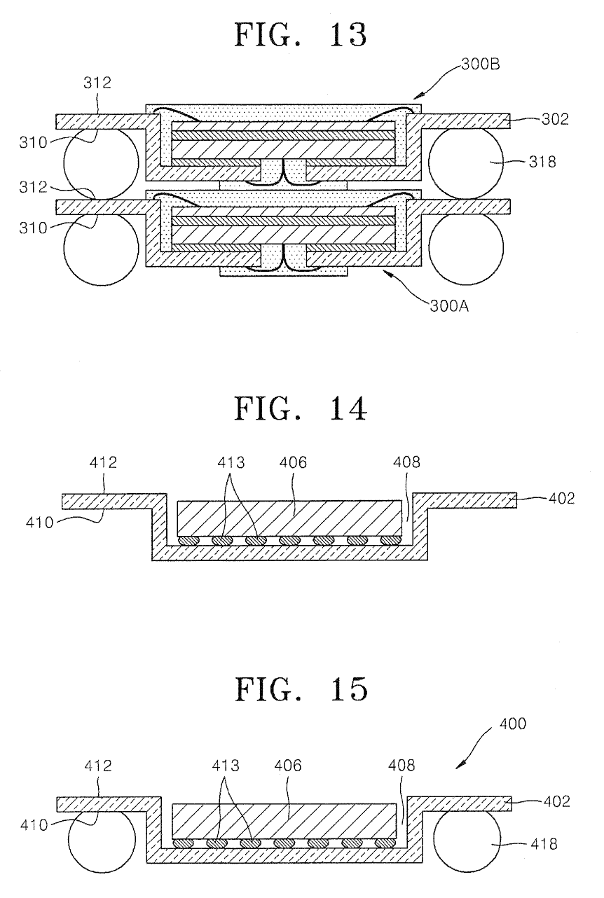

Referring to FIGS. 14 and 15, a wing-type substrate 402 is provided. Here, the wing-type substrate 402 may include a chip pad area 408 in which a slit is not formed and a printed circuit pattern (not shown) for flip chip bonding may be formed on a bottom surface of the chip pad area 408 in advance.

A semiconductor chip 406 includes a bond pad (not shown) on which bond pad bumps 413 are formed. The bond pad may be mounted on the bottom of the chip pad area 408. Here, the semiconductor chip 406 may be mounted in the chip pad area 408 so that a circuit surface faces downward and may be electrically connected to the wing-type substrate 402 using flip chip bonding. Solder balls 418 may be adhered to a solder ball adhering area 410 of the wing-type substrate 402.

A structure of a semiconductor package 400 according to the present embodiment will now be described with reference to FIG. 15.

As shown in FIG. 15, the semiconductor package 400 may include the wing-type substrate 402, the semiconductor chip 406, and the solder balls 418. The wing-type substrate 402 may include the chip pad area 408, which is depressed relative to the solder ball adhering area 410, the solder ball adhering area 410 which is raised relative to the chip pad area 408, and a stack-type solder ball pad 412 which is formed on an opposite surface to the solder ball adhering area 410. The semiconductor chip 406 may be inserted into the chip pad area 408 of the wing-type substrate 402 to be connected to the wing-type substrate 402 through the bumps 413. The solder balls 418 have a diameter that is greater than a height of the wing-type substrate 402.

The semiconductor package 400 exemplarily described above with respect to FIG. 15 is similar structure to the semiconductor package 200 exemplarily described with respect to FIG. 8 but is different from the semiconductor package 200 in that the semiconductor chip 406 mounted in the chip pad area 408 is connected to the wing-type substrate 402 using a flip chip bonding method using the bond pad bumps 413. Thus, a sealing part is not required.

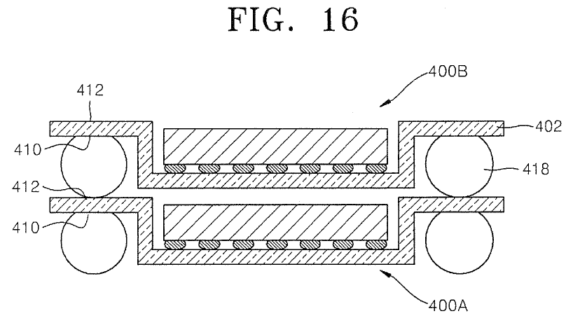

FIG. 16 is a cross-sectional view illustrating a stack-type semiconductor package realized using multiple semiconductor packages such as those exemplarily shown in FIG. 15.

As shown in FIG. 16, the stack-type solder ball pad 412 of a first semiconductor package 400A may be connected to corresponding solder balls 418 of a second semiconductor package 400B to electrically connect the first semiconductor package 400A to the second semiconductor package 400B.

As described above, according to the present invention, even when the diameter of solder balls is reduced, or when a plurality of semiconductor chips are stacked in a semiconductor package to constitute a package body, stacking can be easily performed due to the various structural characteristics of wing-type substrates exemplarily described above. Also, a final thickness of the semiconductor package can be reduced compared to the final thickness of prior art semiconductor packages.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package, comprising:
a wing-type substrate comprising a first surface, a second surface opposite the first surface, a chip pad area, an external terminal area on the first surface and a stack-type terminal pad on the second surface, wherein the chip pad area is lower than the external terminal area;
a semiconductor chip mounted on the wing-type substrate within the chip pad area, wherein the semiconductor chip is electrically connected to the wing-type substrate;
a sealing part on the wing-type substrate, the sealing part sealing the semiconductor chip and the wing-type substrate; and
a conductive connecting member on the external terminal area, wherein a height of the conductive connecting member is greater than a height of the wing-type substrate.

2. The semiconductor package of claim 1, wherein a single semiconductor chip is mounted on the wing-type substrate within the chip pad area.

3. The semiconductor package of claim 1, wherein a circuit surface of the semiconductor chip faces toward the chip pad area.

4. The semiconductor package of claim 3, wherein the semiconductor chip is a center pad-type semiconductor chip comprising a bond pad located in the center of the semiconductor chip.

5. The semiconductor package of claim 4, further comprising a slit within the chip pad area.

6. The semiconductor package of claim 3, wherein the sealing part is on a lower surface of the wing-type substrate.

7. The semiconductor package of claim 1, wherein a circuit surface of the semiconductor chip faces away from the chip pad area.

8. The semiconductor package of claim 7, wherein the sealing part is on an upper surface of the wing-type substrate.

9. The semiconductor package of claim 1, wherein a plurality of semiconductor chips are mounted on the wing-type substrate within the chip pad area.

10. The semiconductor package of claim 9, wherein a bottom surface of at least one of the plurality semiconductor chips is polished.

11. The semiconductor package of claim 9, wherein at least one of the plurality of semiconductor chips has a thickness within a range of between about 50 μm and about 100 μm.

12. The semiconductor package of claim 9, wherein a first one of the plurality of semiconductor chips is mounted within the chip pad area such that a circuit surface of the first one of the plurality of semiconductor chips faces toward the chip pad area and a second one of the plurality of semiconductor chips is mounted within the chip pad area such that a circuit surface of the second one of the plurality of semiconductor chips faces away from the chip pad area.

13. The semiconductor package of claim 12, further comprising a slit within the chip pad area.

14. The semiconductor package of claim 12, wherein the sealing part comprises a first sealing part on a lower surface of the wing-type substrate and a second sealing part on an upper surface of the wing-type substrate.

15. The semiconductor package of claim 12, further comprising terminal pads disposed in two rows within the external terminal area.

16. The semiconductor package of claim 12, further comprising a plurality of stack-type terminal pads disposed in two rows on the second surface.

17. The semiconductor package of claim 1, further comprising a wire electrically connecting the semiconductor chip to the wing-type substrate.

18. The semiconductor package of claim 17, wherein the sealing part seals the semiconductor chip and the wire.

19. The semiconductor package of claim 1, wherein the conductive connecting member comprises a solder ball or a conductive pillar.

20. A stack-type semiconductor package, comprising:
a first semiconductor package having a structure of the semiconductor package of claim 1; and
a second semiconductor package connected to the first semiconductor package through a stack-type terminal pad of the first semiconductor package and having an identical structure to the first semiconductor package.

21. The stack-type semiconductor package of claim 20, further comprising a third semiconductor package connected to the second semiconductor package through a stack-type terminal pad of the second semiconductor package and having an identical structure to the first semiconductor package.

22. A semiconductor package, comprising:
a wing-type substrate comprising a first surface, a second surface opposite the first surface, a chip pad area, an external terminal area on the first surface and a stack-type terminal pad on the second surface, wherein the external terminal area is higher than the chip pad area;
a semiconductor chip within chip pad area and connected to the wing-type substrate by a bump; and
a conductive connecting member coupled to the external terminal area, wherein a height of the conductive connecting member is greater than a height of the wing-type substrate.

23. A stack-type semiconductor package, comprising:
a first semiconductor package having a structure of the semiconductor package of claim 22; and
a second semiconductor package connected to the first semiconductor package through the stack-type terminal pad of the first semiconductor package and having an identical structure to the first semiconductor package.
